(19) United States
(12) Patent Application Publication
(10) Pub. No.: US 2010/0169033 A1
(43) Pub. Date: Jul. 1, 2010

(54) State Of Charge Determination

(76) Inventors: Alf Isaksson, Vasteras (SE); Gunnar Russberg, Vasteras (SE)

Correspondence Address: ST.ONGE STEWARD JOHNSTON & REENS, LLC, 986 Bedford Street, Stamford, CT, 06905-5619, US

(21) Appl. No.: 12/650,744

(22) Filed: Dec. 31, 2009

Related U.S. Application Data
(63) Continuation of application No. PCT/EP2007/005834, filed on Jul. 2, 2007.

(51) Int. Cl. G01R 31/36; G01N 27/416; H02J 7/00

(52) U.S. Cl. 702/63; 324/427; 320/132

(57) ABSTRACT

A method, device and computer program product for determining the state of charge of at least one battery as well as to a power compensator for an electric power transmission line including such a device. The device includes an internal states prediction unit and a state of charge determining unit. The internal states prediction unit makes an internal states prediction of a battery based on a model for the battery, where each internal state is related to the charge distribution in the battery, adjusts the internal states prediction with measured properties of the battery and applies the adjusted internal states prediction in the making of following internal state predictions. The state of charge determining unit provides the estimated state of charge (SOC) as a function of the predicted internal states. The invention allows the provision of improved state of charge estimates.

### CROSS-REFERENCE TO RELATED APPLICATIONS

The present application is a continuation of pending International patent application PCT/EP2007/005834 filed on Jul. 2, 2007 which designates the United States, the content of which is incorporated herein by reference.

### FIELD OF THE INVENTION

The present invention relates to the determination of state of charge of batteries. The invention more particularly relates to a method, device and computer program product for determining the state of charge of at least one battery as well as to a power compensator for an electric power transmission line including such a device.

### BACKGROUND OF THE INVENTION

Batteries are used in many applications. One such application is related to power compensation of power lines.

From U.S. Pat. No. 6,747,370 (Abe) a power compensation system using a high temperature secondary battery is previously known. The objective of the compensation system is to provide an economical, high-temperature secondary battery based energy storage, which has a peak shaving function, a load levelling function and a quality stabilizing function. The known system comprises an electric power supply system, an electric load and an electric energy storage system including a high temperature secondary battery and a power conversion system. The battery is a sodium sulphur battery.

The system is arranged at an end of an electric power line. The load is a factory which under normal operating condition is provided with electric power supply from the power line. In case of power supply failure a high speed switch disconnects the power line and electric power is instead provided from the secondary battery. At the same time a back up generator is started. The known system having a sodium sulphur battery indicates that the power compensating system provides low power during a long time.

In one mode of operation the battery is providing extra energy to the factory during day time while being recharged during night. In order to supply a factory with uninterruptible power there are arranged ten parallel connected battery units of 1280 V, each having a converter of 500 kW. In a further embodiment ten battery units are parallel connected in series with a 5 MW converter. In this embodiment a group of spare batteries is arranged for use with the high temperature battery circuit. In the event of a battery unit having a failure the failed unit is disconnected and the spare group is connected in parallel with the circuit.

From U.S. Pat. No. 6,924,623 (Nakamura) a method and device for judging the condition of a secondary battery is previously known. The objective of the device and method is to provide the judgment more quickly and in more detail as compared with conventional methods and devices. The known method includes the steps of varying the charging current and calculating the quantity of electricity. The disclosed method is preferably directed to finding out the grade of degradation.

In these types of systems it is important to know the state of charge (SOC) of a battery in order to be able to better decide when and how the battery is to be connected to such a power system.

This state of charge is not so easy to determine because the various conditions of the battery that are decisive for the state of charge are internal and cannot readily be measured.

U.S. Pat. No. 6,534,954 describes the use of a Kalman filter or an extended Kalman filter that is used for determining the state of charge of a battery. Using a Kalman filter is a good way to determine the state of charge. The state of charge is according to U.S. Pat. No. 6,534,954 one of the internal states of the filter.

There is room for improvement in the determination of the state of charge of a battery using Kalman filters.

### SUMMARY OF THE INVENTION

The present invention is directed towards providing an improved determination of the state of charge of a battery using a Kalman filter.

One objective of the present invention is to provide a method for determining the state of charge of at least one battery that gives better state of charge estimates.

This objective is according to a first aspect of the present invention achieved through a method for determining the state of charge of at least one battery comprising the steps of:

making an internal states prediction of said battery based on a model for the battery, where each internal state is related to the charge distribution in the battery, adjusting said internal states prediction with measured properties of the battery, applying said adjusted internal states prediction in the making of at least one following internal state prediction, and
providing the estimated state of charge as a function of the predicted internal states.

Another objective of the present invention is to provide a device for determining the state of charge of at least one battery that provides better state of charge estimates.

This objective is according to a second aspect of the present invention achieved through a device for determining the state of charge of at least one battery comprising,

an internal states prediction unit arranged to
make an internal states prediction of said battery based on a model for the battery, where each internal state is related to the charge distribution in the battery,
adjust said internal states prediction with measured properties of the battery,
apply said adjusted internal states prediction in the making of at least one following internal state prediction, and

a state of charge determining unit arranged to provide the estimated state of charge as a function of the predicted internal states.

Another objective of the present invention is to provide a power compensator, which includes a charge determination device that provides better state of charge estimates for at least one battery.

This objective is according to a third aspect of the present invention achieved through a power compensator for an electric power transmission line comprising:
a voltage source converter,
at least one battery, and
a charge control device including
   a battery supply decision unit and
   a charge determination device including
      an internal states prediction unit arranged to
         make an internal states prediction of said battery based on a model for the battery, where each internal state is related to the charge distribution in the battery,
         adjust said internal states prediction with measured properties of the battery, and
         apply said adjusted internal states prediction in the making of at least one following internal state prediction, and
      a state of charge determining unit arranged to provide an estimated state of charge as a function of the predicted internal states

Another objective of the present invention is to provide a computer program product for determining the state of charge of at least one battery that enables the provision of better state of charge estimates.

This objective is according to a fourth aspect of the present invention achieved through a computer program product for determining the state of charge of at least one battery,

comprising computer program code to make a device for determining the state of charge of the battery perform when said code is loaded into said device:
make an internal states prediction of said battery based on a model for the battery,
where each internal state is related to the charge distribution in the battery,
adjust said internal states prediction with measured properties of the battery,
apply said adjusted internal states prediction in the making of at least one following internal state prediction, and
provide the estimated state of charge as a function of the predicted internal states.

The present invention has the advantage of providing an improved determination of the state of charge of a battery, since more than one state is considered. This means that a more reliable decision can be taken on how to use the battery than what has been possible previously.

It should be emphasized that the term “comprises/comprising” when used in this specification is taken to specify the presence of stated features, integers, steps or components, but does not preclude the presence or addition of one or more other features, integers, steps, components or groups thereof.

### BRIEF DESCRIPTION OF THE DRAWINGS

The present invention will now be described in more detail in relation to the enclosed drawings, in which:

FIG. 1 schematically shows a principal circuit of a power compensator according to the present invention,

FIG. 2 shows a side elevation of a part of an energy storage device comprising a plurality of battery units according to the invention,

FIG. 3 schematically shows a cross section of a cylindrical battery having different charged and uncharged areas according to the battery model,

FIG. 4 shows a block schematic of a power compensator including a charge control device,

FIG. 5 shows a block schematic of device for determining the state of charge of a battery according to the present invention being provided in the charge control device,

FIG. 6 schematically shows a number of method steps taken in a method for determining the state of charge of a battery according to the invention,

FIG. 7 schematically shows a number of method steps taken in order to determine the number of states that are to be used when determining the state of charge, and

FIG. 8 schematically shows a computer program product in the form of a CD ROM disc comprising computer program code for carrying out the method of the present invention.

### DETAILED DESCRIPTION OF THE INVENTION

In the following description, for purposes of explanation and not limitation, specific details are set forth such as particular architectures, interfaces, techniques, etc. in order to provide a thorough understanding of the present invention. However, it will be apparent to those skilled in the art that the present invention may be practiced in other embodiments that depart from these specific details. In other instances, detailed descriptions of well known devices, circuits, and methods are omitted so as not to obscure the description of the present invention with unnecessary detail.

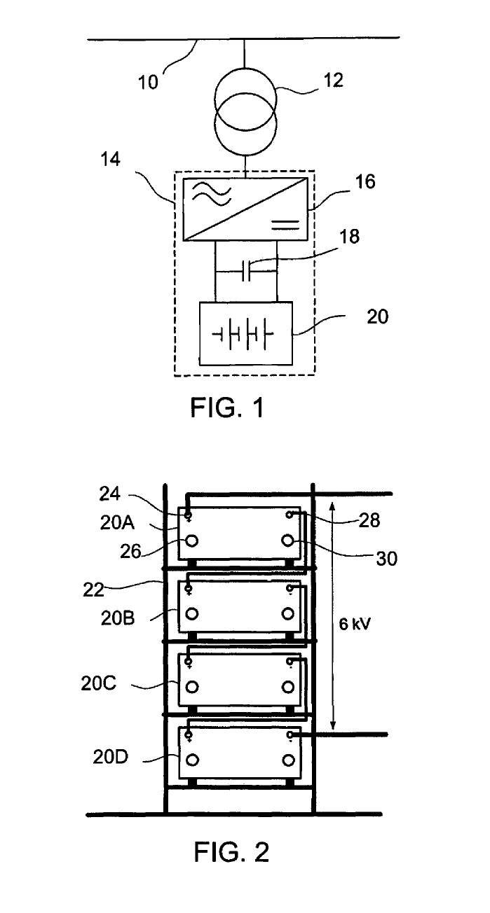

FIG. 1 shows a principal circuit of a power compensator 14 connected to an electric power transmission line 10 via a transformer 12. The power compensator 14 comprises a voltage source converter 16, a capacitor 18 and an energy storage device 20. The energy storage device may here be made up of several batteries. The voltage source converter 16 may include twelve self-commutated semiconductor switches, each of which is shunted by a reverse parallel connected diode. The voltage source converter 16 has an AC side connected to the transformer and a DC side connected to the capacitor 18 and the energy storage device 20.

The energy storage device may include a plurality of series connected batteries 20A, 20B, 20C and 20D. It may also include a number of strings of such series connected batteries, where these strings are connected in parallel with each other. In the embodiment shown in FIG. 2 being a part of a energy storage device 20 four battery units 20A-20D are arranged in a rack 22. Each battery unit has a positive terminal 24 and a negative terminal 28. In the embodiment shown each battery unit has a voltage of 1500 volts and thus the energy storage device containing four batteries connected in series has a voltage level of 6 kV. However there may also be many more batteries in series resulting in a much higher voltage level.

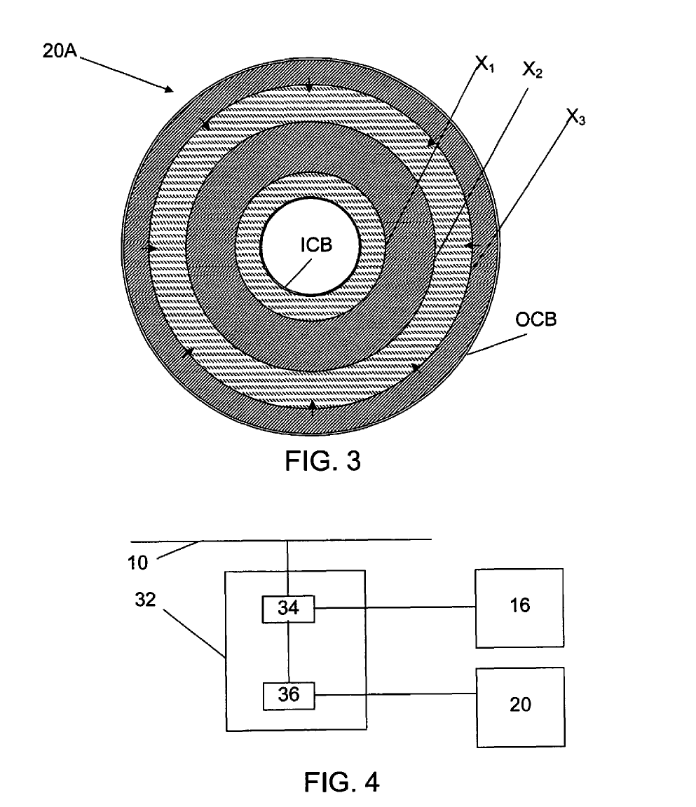

The energy storage device 20 may comprise high energy, high temperature batteries containing sodium/metal chloride battery cells having an operating temperature in the range of 270-340° C. A sodium/metal chloride battery cell comprises an electrolyte contained in a thin barrier of a ceramic material. A cross-section through a model of such a cylindrically shaped battery 20A is shown in FIG. 3. Here it should be realised that the shown cylindrical shape is only exemplifying and that a battery may have any suitable shape. According to the model of this battery, the interior includes various regions. These regions are shown with different patterns in order to indicate charged and uncharged areas of this battery. When the battery is charged or discharged a reacting front is propagating inwardly from the ceramic barrier. Thus both the charging and discharging is propagating in the same direction and starting from the ceramic barrier or outer cell boundary OCB. Resulting from a plurality of charging and discharging cycles there may be left inside the battery a plurality of areas defining power capacity areas and non-power capacity areas. As an example there is a first inner region of power capacity area, i.e. an area with a charge, which stretches radially out from an inner cell boundary ICB or core and outwards to a position x₁. This first area is followed by a second non-power capacitive area, i.e. an area with no charge, stretching from the position x₁ to a position x₂. This second area is in turn followed by a third charged area, which stretches from the position x₂ up to a position x₃. Finally there is a fourth area of uncharged region stretching radially out from the position x₃ to the outer cell boundary OCB. The position x₁ is here the position of a first charge front associated with the second area, the position x₂ the position of a second charge front associated with the third area and the position x₃ the position of a third charge front associated with the fourth area. These positions are here denoted x₁, x₂, x₃ in order to show their association with the use of the model that is to be described later on.

This battery 20A has originally been fully charged and has at some point in time been discharged up to the position of the first charge front x₁. The battery 20A has also been previously charged after this discharging. However, the charging was in this exemplifying case not complete but only made up to the position x₂ of the second charge front. In the example of FIG. 3, the battery is in the process of being discharged. Thus here the third charge front associated with the fourth area is moving radially inwards (as is indicated by arrows), and the third charge front is at a certain instant in time located at the position x₃. If this discharging were to end and be replaced by a charging, a new wave front would be created at the outer cell boundary OCB that would then move inwards as long as charging took place. In this way there may be provided several areas of charged and uncharged electrolyte. This means that whenever a change is made between charging and discharging a new charge front is created. The present invention uses this model of the battery 20A to determine the state of charge (SOC). In this way the model therefore considers the charging history.

Some more details of the power compensator are shown in FIG. 4. Here the power compensator comprises not only the voltage source converter 16 and the energy storage device 20 but also a charge control device 32 containing a plurality of sensors (not shown), a battery supply decision unit 34 and a charge determination device 36.

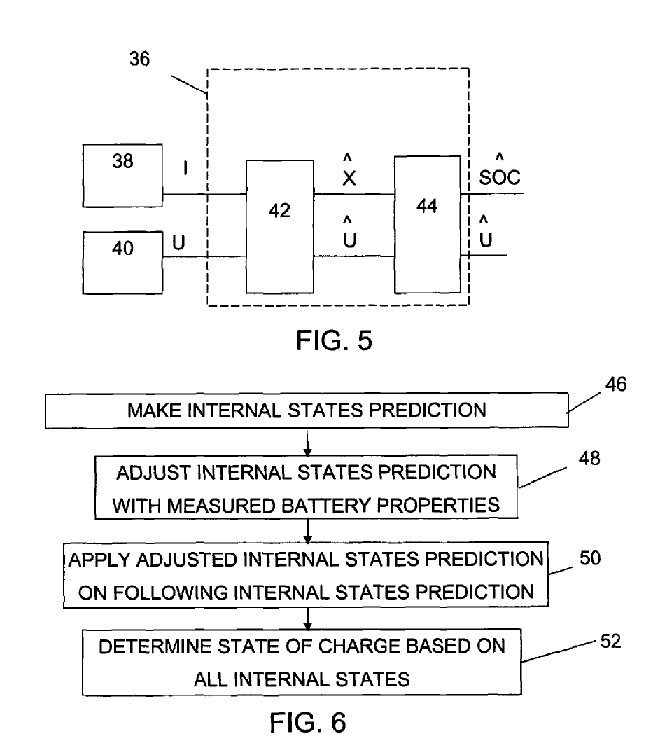

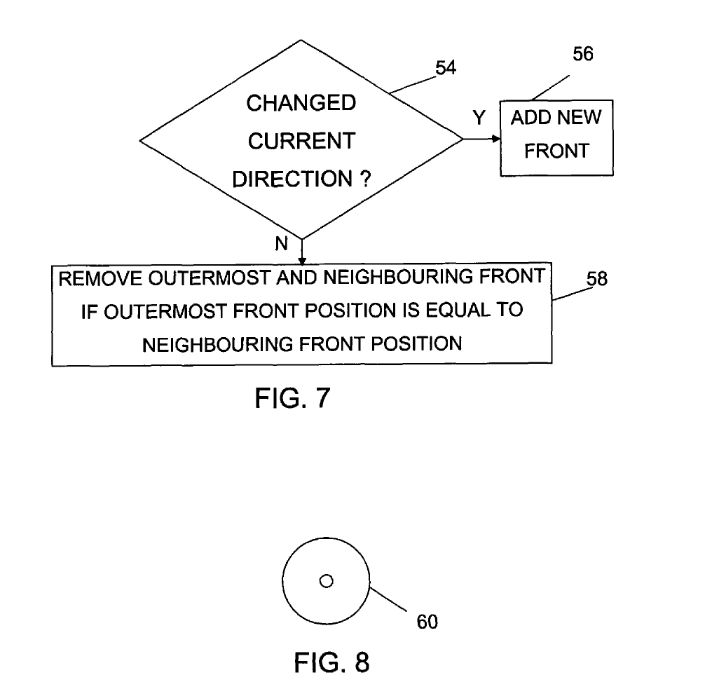

FIG. 5 shows a block schematic of the charge determination device 36 being connected to a current detector 38 and a voltage detector 40. The charge determination device 36 includes an internal states prediction unit 42 being connected to the detectors 38 and 40 and is also connected to a state of charge determining unit 44. The state prediction unit 42 estimates a number of states of the energy storage device, that here correspond to the charge fronts in FIG. 3, and in turn provides estimates of these charge fronts and estimates of the output voltage to the state of charge determining unit 44, which in turn provides an estimated state of charge SOC and an estimated output voltage to the battery supply decision unit. The battery supply decision unit can then decide if the energy storage device is to be connected to the power line or not based on this SOC estimate.

The state estimating unit 42 provides a Kalman filter. According to the invention a number of estimated internal states of a battery model are used in this Kalman filter, where each state corresponds to a charge front as depicted in FIG. 3. In one embodiment of the invention an internal state is the actual position of such a charge front. The description will in the following furthermore be made in relation to one single battery. However, it should be realised that the principle of the invention can in a simple manner be extended to all the batteries of an energy storage device.

The model of the battery shown in FIG. 3 may for a simplified model be described as set of differential equations according to

$${\dot{x}}_{1} = 0$$

$$⋮$$

$${\dot{x}}_{n - 1} = 0$$

$${\dot{x}}_{n} = {f}_{c} ( x ( t ) , i ( t ) )$$

and output equations

u(t)=h(x(t),i(t))

SOC=g(x(t),i(t))

Here a certain state xᵢ (t) is the radial position of a charge front in dependence of time t, i(t) the current input to or output from the battery in dependence of time t, u(t) the voltage of the battery in dependence of time t, x₁ is the position of the innermost charge front, while ƒ, h and g are functions, where the function ƒ is a function that determines the derivate of the state xₙ based on the state x and current i, h is a function that determines the voltage u based on internal state x and current i and g is a function that determines state of charge SOC based on internal state x and current i. There are thus here n states. As can be seen the state of charge is thus a function that depends on the various states x as is the voltage u.

The functions ƒ, h and g are assumed to be nonlinear but differentiable It should here also be realised that the model described is simplified and that a more complex model can readily be made, for instance one which considers also temperature as well where more charge fronts than the highest-order front have a non-zero derivative.

Discretizing the model leads to a discrete-time model.

$${x}_{1} ( k + 1 ) = {x}_{1} ( k )$$

$$⋮$$

$${x}_{n - 1} ( k + 1 ) = {x}_{n - 1} ( k )$$

$${x}_{n} ( k + 1 ) = {f}_{d} ( x ( k ) , i ( k ) )$$

$$u ( k ) = h ( x ( k ) , i ( k ) )$$

where xᵢ (k) is again a state, while k is an instant in time.

Taylor series expansion of the last state equation about an operating point x*(k), i*(k) and u*(k), leads to

Δxₙ(k+1)=a₁Δx₁(k)+a₂Δx₂(k)+ . . . +aₙΔxₙ(k)+bΔi(k)

Δu(k)=c₁Δx₁(k)+ . . . +cₙΔxₙ(k)+dΔi(k)

where,

Δxᵢ(k)=xᵢ(k)−xᵢ*(k),Δi(k)=i(k)−i*(k) and Δu(k)=u(k)−u*(k)

Introducing the state vector

$$Δ x ( k ) = ( \begin{matrix}Δ {x}_{1} ( k ) \\ ⋮ \\ Δ {x}_{n} ( k )\end{matrix} )$$

gives the following linearised discrete-time model”

$$Δ x ( k + 1 ) = A Δ x ( k ) + B Δ i ( k )$$

$$Δ u ( k ) = C Δ x ( k ) + D Δ i ( k )$$

$$with ;$$

$$A = ( \begin{matrix}1 & 0 & … & 0 \\ 0 & ⋱ & & ⋮ \\ 0 & & 1 & 0 \\ {a}_{1} & {a}_{2} & … & {a}_{n}\end{matrix} ) ;$$

$$B = ( \begin{matrix}0 \\ ⋮ \\ 0 \\ b\end{matrix} ) ; ;$$

$$C = ( {c}_{1} … {c}_{n} ) ;$$

$$D = d .$$

Process and measurement noise is then introduced through

u(k)=h(x(k),i(k))+v(k)

where v(k) is Gaussian white noise with covariance R, i.e.

R=Ev²(k)

Under the assumption that there is only process noise (or modelling error) added to the highest-order state equation,

xₙ(k+1)=ƒ_{d}(x(k),i(k))+w(k)

where again the noise w(k) is white and Gaussian with covariance q. Hence the covariance matrix representing all noise contributions to x(k+1) is given by

$$Q = ( \begin{matrix}0 & & & \\ & ⋱ & & \\ & & 0 & \\ & & & q\end{matrix} )$$

Since the model is non-linear a so-called extended Kalman filter (EKF) should be invoked.

The EKF equations are here:

\hat{x}(k+1|k)=f_{d}(\hat{x}(k|k),i(k))

Σ(k+1|k)=AΣ(k|k)A^{T}+Q

\hat{x}(k|k)=\hat{x}(k|k−1)+K(k)(u(k)−h(\hat{x}(k|k−1),i(k)))

Σ(k|k)=(I−K(k)C)Σ(k|k−1)(I−K(k)C)^{T}+K(k)RK^{T}(k)

where \hat{x}(k+1|k) is the predicted estimate of x(k+1) (using data only until time k) and
Σ(k+1|k) is the covariance matrix of \hat{x}(k+1|k)
\hat{x}(k|k) is the filtered estimate of x(k) (after measurement update) and
Σ(k|k), the covariance matrix of \hat{x}(k|k)

Here the Kalman gain is given by

$$K ( k ) = \frac{A Σ ( k \vert k - 1 ) C}{C Σ ( k \vert k - 1 ) {C}^{T} + R}$$

The filter is always initialised when the battery is fully charged and a discharge is started. There is therefore only one state which is known to be exactly at the outer radius of the battery r, i.e.,

\hat{x}(0|0)=r

Since it is assumed that r is known without error, the initial covariance is zero, i.e.

Σ(0|0)=0

The applying of this type of filtering will now be described with reference being made to FIGS. 5 and 6, where the latter shows a flow chart of a method a number of method steps taken in a method for determining the state of charge of a battery according to the invention. According to the present invention, the internal states prediction unit 42 of the charge determination device 36 receives detected currents i over time and provides an estimate of the states x and then particularly of the highest order state xₙ, step 46. Here it also includes noise in the estimation and also provides the covariance or uncertainty. Once a measurement property is obtained, which is here in the form of a voltage u, the Kalman gain is determined. Thereafter the made state estimation is adjusted with the measured properties, step 48. Also the covariance is here adjusted. Here the correction factors for the estimated state and covariance are calibrated with the Kalman gain. Thereafter the state determining unit 42 applies the adjusted internal states prediction in the making of following internal state predictions, i.e. new state estimates are provided based on corrected earlier estimates, step 50. This means that if corrections were made at time k, these are applied for estimations at time k+1. The state estimates are after this correction provided to the state of charge determination unit 44, which goes on and determines the estimate of the state of charge SOC based on the function g of the internal states. This is here done through considering all of the internal states, step 52. This state of charge estimation SOC is then provided to the battery supply determining unit, which can decide when and how long the battery is to be connected to the transmission line in FIG. 1 based on this determination. The charge determination device also provides an estimate of the voltage u, which may also be used in such decisions.

Thus what has been described so far is normal Kalman filtering. However, according to the present invention a number of internal states are determined and corrected based on measured properties. According to the present invention, there are thus several internal states that are together used for estimating the state of charge.

According to the present invention the number of states may furthermore vary. This means that the model is time-varying, not in the numerical values of parameters but in the size of the matrices. The internal states prediction unit 42, receives current values of the battery when performing predictions. If the current is positive a charging is made, while if the current is negative a discharging is made. As mentioned above a change of current direction gives rise to a new charge front at the battery outer cell boundary BOC. Therefore if a change in the current direction is detected, step 54, a new charge front, i.e. a new state is created, step 56. This state is thus the highest order state, which then changes based on time and corresponds to an inward movement towards the core of the battery. The formerly highest order state will therefore now be a state the derivate of which is zero, while the new highest order state caused by the change of direction will be estimated starting from its original position at the outer radius of the battery. This also means that the above mentioned vectors and matrices will get larger in order to reflect this change. If however no change of direction is detected, step 54, the movement of the outermost front or state is compared with the neighbouring front of the neighbouring lower order state and if these become equal both these states are removed from the state determination, step 58. They thus cancel out each other. If the battery of FIG. 3 is taken as an example, this means that if the state x₃ of FIG. 3 would continue to move so that it gets equal to the state x₂, both these states would be removed and state x₁ would now be the highest order state which gets predicted. This thus means that there is a reduction of the vectors and matrices.

In the Kalman filter these two events should be treated as
1. When after a measurement update \hat{x}ₙ(k|k)≦\hat{x}ₙ₋₁(k|k) then remove the last two states from \hat{X}(k|k) and set Σ(k|k) to be of a dimension (n−2)×(n−2) retaining only the upper left-hand submatrix of this dimension. Also re-compute A, B and C matrices of this new dimension.
2. If i(k) changes sign compared to previous iteration, then extend the state estimate with a new element \hat{x}ₙ(k|k)=r Then also modify the covariance matrix as

$$Σ ( k \vert k ) = [ \begin{matrix}Σ ( k \vert k ) & 0 \\ 0 & 0\end{matrix} ]$$

However, since when dealing with sampled data there is an uncertainty as to when exactly the current changed its sign, it may make sense not to initialize the extra elements to zero. At least the n:th diagonal element should probably be given an uncertainty that corresponds to a fraction of the other diagonal elements of Σ(k|k).Furthermore, one may want to low-pass filter i(k) or introduce some hysteresis in the logic for the sign shift in order not to open up too many new states if the current signal is noisy.

In this way an improved determination of the state of charge is obtained, since more than one state is considered. The determination furthermore considers the charging history, since it considers the amount of charging and discharging that has been made. This means that a more reliable decision can be taken on how to use the battery than was possible previously. This may be vital in deciding if to use battery power in power line applications.

The charge control device according to the present invention may be implemented through one or more processors together with computer program code for performing its functions. The program code mentioned above may also be provided as a computer program product, for instance in the form of one or more data carriers carrying computer program code for performing the functionality of the present invention when being loaded into the translating device. One such carrier 60, in the form of a CD ROM disc is generally outlined in FIG. 8. It is however feasible with other data carriers, like diskettes, memory sticks or USB memories. The computer program code can furthermore be provided as pure program code on an external server and fetched from there for provision in the charge control device.

While the invention has been described in connection with what is presently considered to be most practical and preferred embodiments, it is to be understood that the invention is not to be limited to the disclosed embodiments, but on the contrary, is intended to cover various modifications and equivalent arrangements. It is for instance possible to leave out noise and covariance from the determinations in the state determination unit. The internal states used do not have to be limited to the position of a charge front, they can for instance as an alternative be related to the extension of the same amount of charge in a battery. They can in fact be any internal state of a battery that is related to the charge distribution. It is of course also possible to have temperature as a variable to consider in the model. There may also be more than one set of charge fronts; one per chemical component. It is thus possible to replace the above described charge fronts with a set of charge fronts, where each such set is associated with a different chemical component of the battery. Here the cancellation of charge fronts is done per chemical component. This means that the number of states per chemical component or set may vary in the battery. This allows an even more reliable state of charge to be determined for the battery. The states of one set may furthermore interact with states of another set. This also means that in such a case, also inner states may have positions that vary with time and not only the outer states of the different sets closest to the outer cell boundary that was described above. The invention is furthermore not limited to supply of power to a power line, but can be used in any application where the state of charge is of interest. Therefore the present invention is only to be limited by the following claims.

1. A method determining the state of charge (SOC) of at least one battery comprising the steps of:
making an internal states prediction of said battery based on a model for the battery, where each internal state is related to the charge distribution in the battery, adjusting said internal states prediction with measured properties of the battery, applying said adjusted internal states prediction in the making of at least one following internal state prediction, and
providing the estimated state of charge (SOC) as a function of the predicted internal states.

2. The method according to claim 1, wherein the number of internal states in said model is variable and depends on the amount of charging and discharging of the battery.

3. The method according to claim 2, wherein the charging of the battery after a previous discharging or the discharging of the battery after a previous charging provides at least one new internal state in said model.

4. The method according to claim 2, wherein if one internal state reaches the same value as the value of a neighbouring internal state, these two internal states cancel out each other.

5. The method according to claim 2, wherein the model of the battery considers the charging history.

6. The method according to claim 2, wherein each internal state corresponds to a position (x₁, x₂, x₃) of a charge front in the battery.

7. The method according to claim 6, wherein there are a number of sets of charge fronts, where each set corresponds to a different chemical component of the battery.

8. The method according to claim 7, wherein if one internal state in a set reaches the same value as the value of a neighbouring internal state of the same set, these two internal states cancel out each other.

9. The method according to claim 2, wherein each internal state corresponds to the extension of the same amount of charge in said battery.

10. The method according to claim 1, wherein the internal states are determined also in dependence of the temperature of the battery.

11. The method according to claim 1, further comprising the step of using the estimated state charge when deciding if to supply power from the battery or not in a power supply system.

12. A Device for determining the state of charge (SOC) of at least one battery comprising,
an internal states prediction unit arranged to
make an internal states prediction of said battery based on a model for the battery, where each internal state is related to the charge distribution in the battery,
adjust said internal states prediction with measured properties of the battery, and
apply said adjusted internal states prediction in the making of at least one following internal state prediction, and
a state of charge determining unit arranged to provide the estimated state of charge (SOC) as a function of the predicted internal states.

13. The device according to claim 12, wherein the number of internal states in said model is variable and depends on the amount of charging and discharging of the battery.

14. The device according to claim 13, wherein the charging of the battery after a previous discharging or the discharging of the battery after a previous charging provides at least one new internal state in said model.

15. The device according to claim 13, wherein if one internal state reaches the same value as the value of a neighbouring internal state, these two internal states cancel out each other.

16. The device according to claim 13, wherein the model of the battery considers the charging history.

17. The device according to claim 13, wherein each internal state corresponds to the position (x₁, x₂, x₃) of a charge front in the battery.

18. The device according to claim 17, wherein there are a number of sets of charge fronts, where each set corresponds to a different chemical component of the battery

19. The device according to claim 18, wherein if one internal state in a set reaches the same value as the value of a neighbouring internal state of the same set, these two internal states cancel out each other.

20. The device according to claim 13, wherein each internal state corresponds to the extension of the same amount of charge in the battery.

21. The device according to claim 12, wherein the internal states are determined also in dependence of the temperature of the battery.

22. A power compensator for an electric power transmission line comprising:
a voltage source converter
at least one battery, and
a charge control device including
a battery supply decision unit and
a charge determination device including
an internal states prediction unit, arranged to
make an internal states prediction of said battery based on a model for the battery, where each internal state is related to the charge distribution in the battery
adjust said internal states prediction with measured properties of the battery, and
apply said adjusted internal states prediction in the making of at least one following internal state prediction, and
a state of charge determining unit arranged to provide an estimated state of charge (SOC) as a function of the predicted internal states.

23. The power compensator according to claim 22, wherein said battery supply decision unit is arranged to use the estimated state of charge (SOC) when deciding if to supply power from the battery or not in a power supply system.

24. A computer program product for determining the state of charge (SOC) of at least one battery,
comprising computer program code to make a device for determining the state of charge of the battery perform when said code is loaded into said device:
make an internal states prediction of said battery based on a model for the battery,
where each internal state is related to the charge distribution in the battery,
adjust said internal states prediction with measured properties of the battery,
apply said adjusted internal states prediction in the making of at least one following internal state prediction, and
provide the estimated state of charge (SOC) as a function of the predicted internal states.

25. The method according to claim 3, wherein if one internal state reaches the same value as the value of a neighbouring internal state, these two internal states cancel out each other.
